(19) United States
(12) Patent Application Publication
(10) Pub. No.: US 2007/0134898 A1
(43) Pub. Date: Jun. 14, 2007

(54) Semiconductor device manufacturing method

(76) Inventors: Shinji Takeoka, Osaka (JP); Junji Hirase, Osaka (JP); Akio Sebe, Osaka (JP); Naoki Kotani, Hyogo (JP); Gen Okazaki, Hyogo (JP); Kazuhiko Aida, Chiba (JP)

Correspondence Address: MCDERMOTT WILL & EMERY LLP, 600 13TH STREET, N.W., WASHINGTON, DC, 20005-3096, US

(21) Appl. No.: 11/581,002

(22) Filed: Oct. 16, 2006

(30) Foreign Application Priority Data
Dec. 8, 2005 (JP) 2005-354493

(51) Int. Cl. H01L 21/4763

(52) U.S. Cl. 438/592

(57) ABSTRACT

After a Ni film is deposited on a substrate on which a gate silicon layer is formed, a mask is formed above the gate silicon layer. Then, the Ni film is etched so as to leave a part of the Ni film which is located on the gate silicon layer. This restricts sideways supply of Ni present on the sides of the gate silicon layer. Thereafter, thermal treatment is performed to silicidate the gate silicon layer entirely.

### BACKGROUND OF THE INVENTION

1. Field of the Invention

The present invention relates to a method for manufacturing a field effect transistor using a metal gate electrode, and particularly relates to a method for manufacturing a FUSI (Fully Silicided) gate electrode.

2. Background Art

In association with scaling down of design rules in semiconductor devices, circuit integration has progressed remarkably, so that more than hundred millions of field effect transistors such as MIS transistors can be mounted on a single chip. In order to reduce such a chip in size, metallization of gate electrodes is demanded in addition to development of micro-fabrication techniques such as a lithography technique, an etching technique, and the like of the order of several-ten nanometers in processing precision.

Conventionally, polysilicon has been used as a material of the gate electrodes of the MIS transistors. In the case where semiconductor is used as a material of the gate electrodes, however, the gate electrodes are depleted to cause an increase in electrical oxide film thickness. The “electrical oxide film thickness” herein means a thickness of a gate oxide film including a layer substantially behaving as a gate oxide film as a result of depletion. In the approximately 90 nm gate length generation, a desired electrical gate oxide film thickness is approximately 2.0 to 2.4 nm. The electrical gate oxide film thickness increases approximately 0.3 nm in association with depletion of the gate electrode, and therefore, the above disadvantage can be dealt with anyway by thinning the actual gate oxide film. As reduction in the gate length progresses to 65 nm and further to the 45 nm, the electrical gate oxide film thickness is demanded to be thinner. For example, in the 45 nm gate length generation, the electrical gate oxide film thickness is desired to be about 1.2 to 1.6 nm. With the use of polysilicon gate electrode in this generation, it becomes difficult for any conventional schemes to cope with the electrical gate oxide film thickness increased in association with depletion of the gate electrode. For this reason, development of a novel material of the gate electrode has been desired.

In recent years, a FUSI (Fully Silicided) gate technique as a scheme for preventing depletion of the gate electrode gathers attention which causes a silicide formation reaction of the entire gate electrode to a metal such as cobalt (Co), Nickel (Ni), or the like (Aoyama et al., IEDM Tech. Dig. pp. 95-98, 2004). A technique for causing the silicide formation reaction of only the upper part of the gate electrode to Co, Ni, or the like has been employed conventionally for reducing the resistance of the gate electrode. Accordingly, the FUSI gate technique is a direct extension of the conventional technique and a promising technique in view of no novel material employed.

### SUMMARY OF THE INVENTION

In the FUSI gate technique, however, the silicide formation reaction is caused after deposition of a large amount of metal, such as Ni, on polysilicon to cause a silicide phase formed by Ni supply to vary according to the amount of supplied Ni, resulting in unstable transistor characteristics.

FIG. 4A to FIG. 4C are sections showing one example of a conventional FUSI formation flow.

First, as shown in FIG. 4A, along a typical flow for forming a MIS transistor, a gate insulting film 1101 and a polysilicon layer 1102 are formed sequentially on a semiconductor substrate 1100, and then, an impurity is implanted to the semiconductor substrate 1100 for forming an extension region (not shown). Next, a sidewall 1103 formed of an insulting film and source/drain regions are formed. Then, an interlayer insulating film 1104 is deposited on the substrate. The upper face of the polysilicon layer 1102 is exposed by chemical mechanical polishing (CMP), and then, the height of the polysilicon layer 1102 is adjusted using a chemical solution or by dry etching.

Subsequently, as shown in FIG. 4B, a Ni film 1105 is deposited on the entirety of the upper face of the substrate. Next, as shown in FIG. 4C, thermal treatment is performed for forming silicide in the substrate. Thus, the entire gate electrode is silicided.

As can be understood from FIG. 4C, in the thus formed gate electrode, parts near the sidewalls 1103 and the central part have silicide phases different from each other. In detail, since Ni is supplied a lot to the parts near the sidewalls 1103 because of sideways supply of Ni present on the interlayer insulating film 1104, the parts of the gate electrode forms Ni₃Si layers 1106. On the other hand, since the Ni supply is restricted in the central part according to the thickness of the Ni film deposited only on the polysilicon layer 1102, the central part of the gate electrode forms a NiSi layer 1107. Ni₃Si and NiSi are different from each other in work function, and therefore, the characteristics of a transistor having such a structure are significantly unstable.

The present invention has its object of providing a method for manufacturing a semiconductor device including a FUSI gate electrode having a homogeneous silicide phase by providing a countermeasure for coping with the above problems.

In order to solve the above conventional problems, in the present invention, a part of a metal layer is removed using a mask formed above a gate silicon layer, and then, the gate silicon layer is silicided.

Specifically, a semiconductor device manufacturing method according to the present invention includes the steps of: (a) forming a first gate silicon layer on a semiconductor substrate with a first gate insulating film interposed; (b) forming a metal film on the semiconductor substrate on which the first gate silicon layer is formed; (c) forming a first mask on a part of the metal film which is located above the first gate silicon layer; (d) removing a part of the metal film with the use of the first mask so as to leave the metal film on the first gate silicon layer; and (e) forming a first gate electrode made of metal silicide by causing a reaction of the first gate silicon layer to the metal film left on the first gate silicon layer after the step (d).

In the above method, silicidation is performed in the step (e) after removing a surplus part of the metal film in the step (d), so that the material of the metal film is supplied evenly to every part of the first gate silicon layer during the silicide formation reaction, leading to formation of the first gate electrode made of metal silicide having a homogeneous crystal phase. Accordingly, the gate electrode is less depleted, and a semiconductor device, such as a MIS transistor, having stable characteristics can be attained.

Further, the above method may further include the steps of: (f) forming a sidewall made of an insulating material on each side face of the first gate silicon layer after the step (a) and before the step (b); and (g) setting the upper level of the first gate silicon layer to be lower than the upper end of the sidewall by removing an upper part of the first gate silicon layer before the step (b). In this case, appropriate adjustment of the upper level of the first gate silicon layer attains adjustment of the upper level of the first gate electrode after the silicide formation reaction.

Further, the first mask may be a resist mask.

The first gate silicon layer may be made of amorphous silicon or polysilicon.

In addition, appropriate adjustment of the thicknesses of gate silicon layers and metal films left thereon attains gate electrodes made of metal silicide having different crystal phases. Accordingly, the silicide formation reaction after provision of two or more gate silicon layers having different thicknesses enables easy formation of FUSI gate electrodes having different crystal phases on a single substrate.

The metal silicide formed in the step (e) includes Ni silicide, Co silicide, Pt silicide, or the like, for example.

### BRIEF DESCRIPTION OF THE DRAWINGS

FIG. 1A to FIG. 1G are sections showing a semiconductor device manufacturing method according to Embodiment 1.

FIG. 2A to FIG. 2D are sections showing a semiconductor device manufacturing method according to Embodiment 2.

FIG. 3A to FIG. 3C are sections showing a semiconductor device manufacturing method according to Embodiment 2.

FIG. 4A to FIG. 4C are sections showing of one example of a conventional FUSI formation flow.

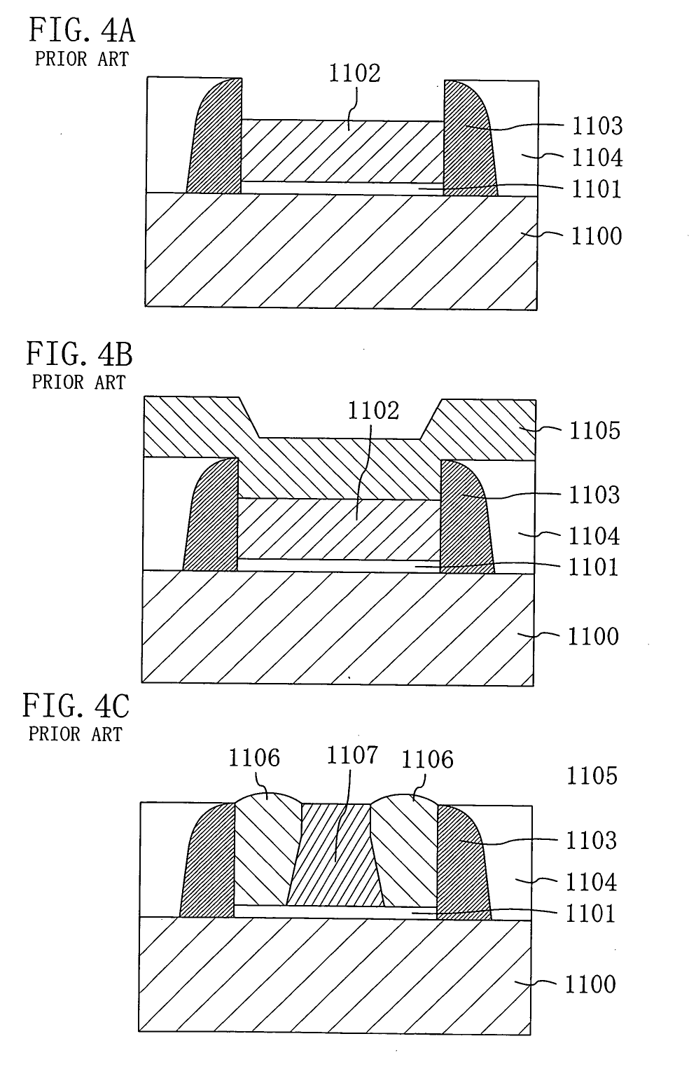

### DESCRIPTION OF THE PREFERRED EMBODIMENTS

### Embodiment 1

A semiconductor device manufacturing method according to Embodiment 1 of the present invention will be described below with reference to the accompanying drawings.

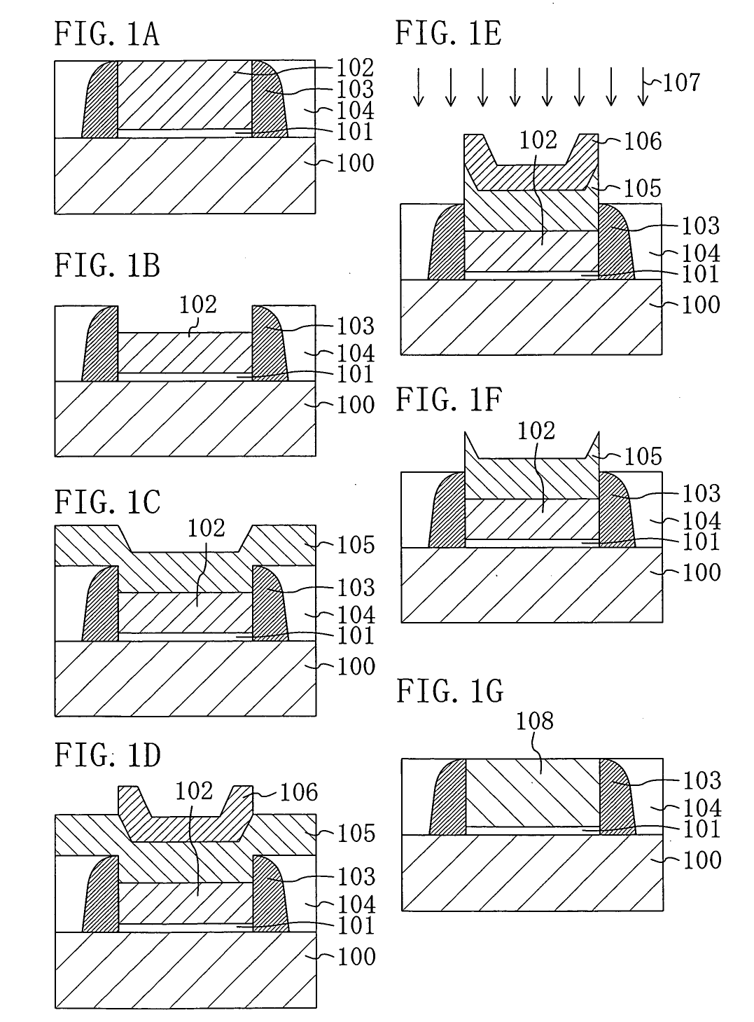

FIG. 1A to FIG. 1G are sections showing the semiconductor device manufacturing method according to Embodiment 1.

First, as shown in FIG. 1A, a SiON film having a thickness of 2 nm and a polysilicon layer having a thickness of 100 nm are deposited sequentially on a semiconductor substrate 100 made of silicon (Si) or the like, and a gate insulating film 101 made of SiON and having a thickness of approximately 2 nm and a gate silicon layer 102 having a thickness of 100 nm and a gate length of approximately 100 nm are formed by etching respective parts of the SiON film and the polysilicon film. After an impurity ion is implanted into the semiconductor substrate 100 with the use of the gate silicon layer 102 as a mask for forming an extension region (not shown), a sidewall 103 formed of an insulating film and having a height of 100 nm is formed at each side face of the gate insulating film 101 and the gate silicon layer 102 by a known method. An impurity is implanted into the semiconductor substrate 100 with the use of the gate silicon layer 102 and the sidewall 103 as a mask to form a source region and a drain region (the source region and the drain region are not shown). An interlayer insulating film 104 is deposited on the substrate. Then, the interlayer insulating film 104 is polished by CMP until the upper face of the gate silicon layer 102 is exposed.

Subsequently, as shown in FIG. 1B, the gate silicon layer 102 is removed selectively, downwardly from the upper part thereof by, for example, dry etching so that the thickness (height) of the gate silicon layer 102 becomes, for example, 50 nm. This results in that the upper level of the gate silicon layer 102 is lower than the upper end of the sidewall 103 and the upper level of the interlayer insulating film 104. In this step, wet etching using a chemical solution capable of selectively removing the gate silicon layer 102 may be performed on the sidewall 103 and the interlayer insulating film 104.

Next, as shown in FIG. 1C, a Ni film 105 having a thickness of 50 nm is deposited on the upper face of the substrate by sputtering.

Thereafter, as shown in FIG. 1D, a mask 106 is formed on a part of the Ni film 105 which is located above the gate silicon layer 102. The mask 106 may be a hard mask made of SiO₂ or a resist mask.

In a case using the resist mask, a resist is applied on the Ni film 105, and then, the thus formed resist mask is patterned by lithography or the like so that a part of the resist mask which is located above the gate silicon layer 102 is left.

Alternatively, referring to the hard mask, it can be formed in such a manner that a film made of SiO₂ or the like is formed on the entirety of the substrate, and then, a part other than a part formed above the gate silicon layer 102 is removed by etching. Or, the hard mask can be formed, with the fact taken into consideration that the upper face portion of the Ni film 105 is recessed above the gate silicon layer 102, in such a manner that an insulating film made of SiO₂ or the like is formed on the entirety of the Ni film 105, and then, a part of the insulating film which is located above the gate silicon layer 102 is left by polishing by CMP.

Subsequently, as shown in FIG. 1E, a part of the Ni film 105 is removed by etching 107 using the mask 106 so that the Ni film 105 is left on the gate silicon layer 102.

Next, as shown in FIG. 1F, the mask 106 is removed.

Thereafter, as shown in FIG. 1G, the substrate is subjected to thermal treatment at a temperature of 450° C. to cause a silicide formation reaction of the gate silicon layer 102 to the Ni film 105. This leads to formation of a MIS transistor including a gate electrode 108 having a homogeneous NiSi phase.

The semiconductor device of the present embodiment formed by the above described method includes: the semiconductor substrate 100 made of silicon or the like; the gate insulating film 101 made of SiON or the like and formed on the semiconductor substrate 100; the gate electrode 108 made of Ni silicide of which constituent is entirely homogeneous and formed on the gate insulating film 101; the sidewall 103 made of an insulating material and formed at each side face of the gate electrode 108; the extension region (not shown) including the impurity at a low concentration and formed in the region of the semiconductor substrate 100 which is located below each end of the gate electrode 108; and the source region and the drain region (not shown) including the impurity at a high concentration and formed in a region of the semiconductor substrate 100 which is located on the respective sides of the gate electrode 108.

In the method in the present embodiment, the mask 106 is formed above the gate silicon layer 102 after formation of the Ni film 105 so that only a part of the Ni film 105 is left directly on the gate silicon layer 102 before the silicide formation step shown in FIG. 1G. The silicide formation reaction of the Ni film 105 left thereon to the gate silicon layer 102 subsequent thereto enables even Ni supply to every part of the gate silicon layer 102. Accordingly, a semiconductor device including a FUISI gate electrode of which constituent is homogeneous can be manufactured. Hence, employment of the method in the present embodiment suppresses depletion of the gate electrode and enables manufacture of a MIS transistor of which characteristics are stable.

Further, in the method in the present embodiment, when the film thickness ratio of the silicon gate film 102 to the Ni film 105 formed on the gate silicon layer 102 is changed, a composition of silicide composing the gate electrode 108 can be selected arbitrarily. In the present embodiment, the film thickness ratio of the gate silicon layer 102 to the Ni film 105 is set substantially to 1:1 for setting the composition of the gate electrode 108 to be NiSi.

The thicknesses of the gate silicon layer 102 and the Ni film 105 are set to 50 nm before the silicide formation reaction in the present embodiment, but the thicknesses thereof are not limited to this value. Wherein, for forming NiSi, the film thickness ratio of the gate silicon layer 102 to the Ni film 105 is preferably set to 1:1 as a criterion. Further, another Ni silicide of which constituent is homogeneous, such as Ni₃Si, NiSi₂, or the like may be formed by changing the film thickness ratio of the gate silicon layer 102 to the Ni film 105.

The mask 106 formed in the step shown in FIG. 1D is preferably overlaid with the entirety of the gate silicon layer 102 completely when viewed in plan. However, about 30 nm displacement in the direction of the gate length may be ignorable. Even with approximately 30 nm displacement of the mask 106 from the end of the gate silicon layer 102 when viewed in plan, the gate electrode 108 can have a homogeneous silicide phase. In this case, the film thickness ratio of the gate silicon layer 102 to the Ni film 105 may not be necessarily set to 1:1. Specifically, when the volume ratio of the gate silicon layer 102 to the Ni film 105 formed on the gate silicon layer 102 is nearly 1:1, the gate electrode 108 can be formed of which composition is NiSi entirely.

In the example shown in FIG. 1, the upper part of the gate silicon layer 102 is removed before deposition of the Ni film 05 on the substrate so that the upper level of the gate silicon layer 102 becomes lower than the upper level of the interlayer insulating film 104 (the step shown in FIG. 1B), but this step may be omitted. In other words, the Ni film 105 may be formed using the mask 106 on the gate silicon layer 102 of which upper level is equal to that of the interlayer insulating film 104. In this case, the silicide formation reaction increases the volume of the gate electrode 108 when compared with the volume of the original gate silicon layer 102, resulting in that the upper face of the gate electrode 108 rises higher than the upper level of the interlayer insulating film 104.

Though the conductivity type of the MIS transistor is not referred to specifically in the semiconductor device manufacturing method in the present embodiment, a MIS transistor of either type of N-channel and P-channel can be manufactured.

The above description refers to an example where the Ni film 105 is formed on the gate silicon layer 102 for Ni silicidation, but a metal film of Co, Pt, or the like, for example, which are capable of forming silicide with Si, may be formed rather than the Ni film. Plural kinds of silicide of Co or the like different in composition would be formed with Si, wherein employment of the method in the present embodiment attains formation of a FUSI gate electrode made of desired silicide of which constituent is homogeneous. For example, in a case using Co, a FUSI gate electrode made of CoSi or CoSi₂ can be manufactured. In a case using Pt, a FUSI gate electrode made of any one of PtSi, Pt₃Si, and Pt₂Si can be manufactured.

In addition, the SiON film is used as the gate insulating film in the method in the present embodiment, but a FUSI gate electrode having a homogeneous constituent can be formed by the same method even using another insulting film, such as a high-k film or the like.

### Embodiment 2

A semiconductor device manufacturing method according to Embodiment 2 of the present invention will be described below with reference to the accompanying drawings.

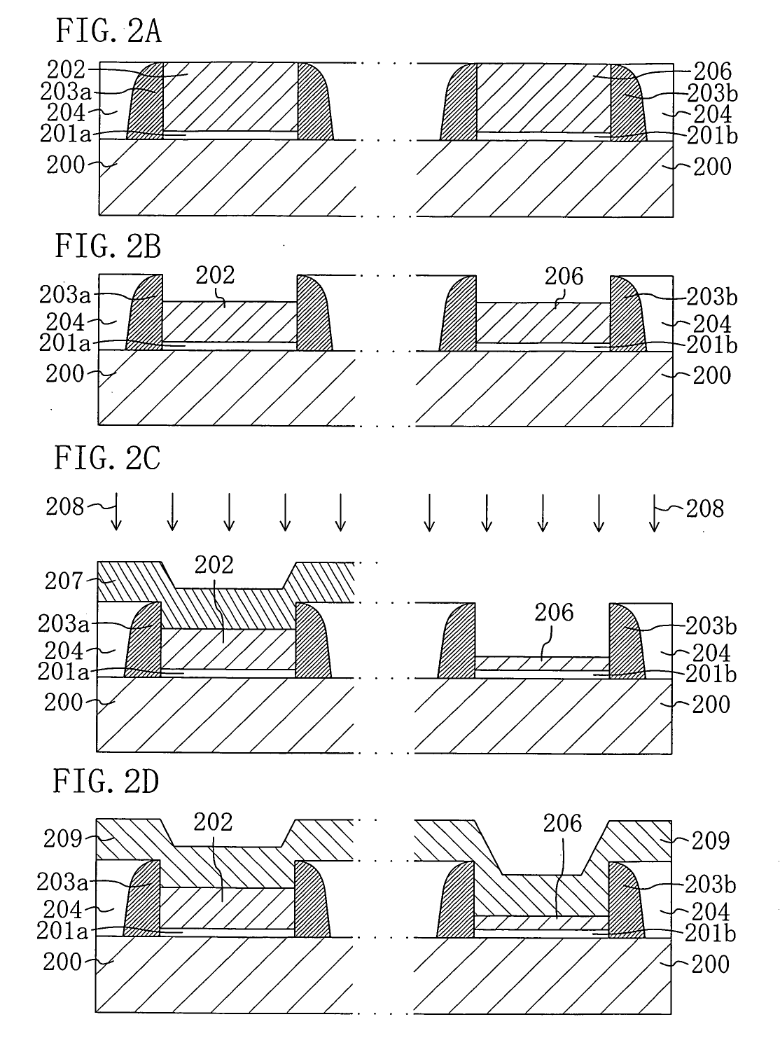

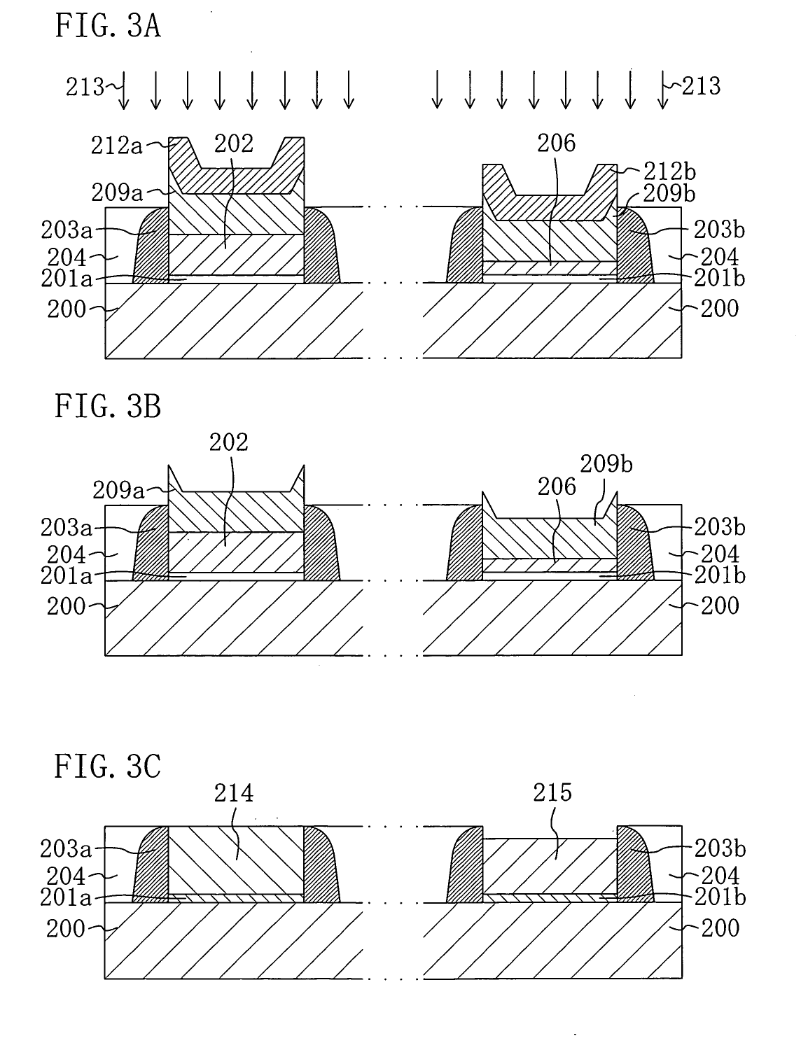

FIG. 2A to FIG. 2D and FIG. 3A to FIG. 3C are sections showing the semiconductor device manufacturing method according to Embodiment 2. The present embodiment relates to a method for manufacturing on a single wafer MIS transistors including FUSI gate electrodes having silicide phases different from each other. Description will be given herein to a manufacturing method where a NiSi phase and a Ni₃Si phase are formed as a gate electrode of a N-channel MIS transistor (NMIS) and a gate electrode of a P-channel MIS transistor (PMIS), respectively. In each of FIG. 2A to FIG. 2D and FIG. 3A to FIG. 3C, a NMIS formation region and a PMIS formation region are shown on the left hand and the right hand, respectively.

First, as shown in FIG. 2A, a gate insulating film 201a, a first gate silicon layer 202, and a sidewall 203a are formed on the NMIS formation region of a semiconductor substrate 200 including a p-type impurity by the same method as in Embodiment 1. Further, a source region and a drain region (not shown) which include a n-type impurity are formed in regions of the semiconductor substrate 200 which are located below the respective ends of the first gate silicon layer 202. As well, a gate insulating film 201b, a second gate silicon layer 206, and a sidewall 203b is formed on the PMIS formation region of the semiconductor substrate 200 including a n-type impurity, and a source region and a drain region (not shown) which include a p-type impurity are formed in regions of the semiconductor substrate 200 which are located below the respective ends of the second gate silicon layer 206. It is noted that before the sidewall 203a is formed, a first extension region including a n-type impurity may be formed in a region of the semiconductor substrate 200 which is located below each end of the first gate silicon layer 202. Also, a second extension region including a p-type impurity may be formed in a region of the semiconductor substrate 200 which is located below each end of the second gate silicon layer 206. Then, an insulating film is deposited on the substrate, and the thus formed insulating film is polished by CMP until both the first gate silicon layer 202 and the second gate silicon layer 206 are exposed, thereby forming an interlayer insulating film 204. The first gate silicon layer 202 and the second gate silicon layer 206 are made of polysilicon, for example.

Each height (thickness) of the first gate silicon layer 202 and the second gate silicon layer 206 after this step is 100 nm. Each height of the sidewalls 203a and 203b is 100 nm as well as that of the gate silicon layers 202, 206.

Next, as shown in FIG. 2B, etching is performed to remove a part of the polysilicon first gate silicon layer 202 and a part of the polysilicon second gate silicon layer 206 so that each thickness of the first gate silicon layer 202 and the second gate silicon layer 206 becomes 60 nm.

Subsequently, as shown in FIG. 2C, a resist mask 207 is formed only on the NMIS formation region by lithography, and etching 208 is performed on the second gate silicon layer 206 with the first gate silicon layer 202 covered with the thus formed resist mask 207. Whereby, the second gate silicon layer 206 has a thickness of 20 nm. In this step, the first gate silicon layer 202 is not etched and still has a thickness of 60 nm. A hard mask made of SiO₂ or the like may be used rather than the resist mask 207. Further, the first gate silicon layer 202 and the second gate silicon layer 206 of which thicknesses are different from each other may be formed by any other process other than the process described herein.

Thereafter, as shown in FIG. 2D, after the resist mask 207 is removed, a Ni film 209 is deposited on the entire surface of the substrate including the first gate silicon layer 202 and the second gate silicon layer 206 so as to have a thickness of 60 nm.

Next, as shown in FIG. 3A, a resist mask 212a is formed on a region of the Ni film 209 which is overlaid with the first gate silicon layer 202 when viewed in plan while a resist mask 212b is formed on a region of the Ni film 209 which is overlaid with the second gate silicon layer 206. Then, an exposed part of the Ni film 209 is removed by etching 213. Whereby, a part (a partial Ni film 209a) and a part (a partial Ni film 209b) of the Ni film 209 are left on the first gate silicon layer 202 and the second gate silicon layer 206, respectively.

Subsequently, as shown in FIG. 3B, the resist masks 212a, 212b are removed. Herein, the film thickness ratio of the first gate silicon layer 202 to the partial Ni film 209a is approximately 1:1, and that of the second gate silicon layer 206 to the partial Ni film 209b is approximately 1:3.

Thereafter, as shown in FIG. 3C, the substrate is subjected to a treatment at 450° C. for causing a silicide formation reaction. In this step, a reaction of the partial Ni film 209a to the first gate silicon layer 202 forms a first gate electrode 214 having a homogeneous NiSi phase while a reaction of the partial Ni film 209b to the second gate silicon layer 206 forms a second gate electrode 215 having a homogeneous Ni₃Si phase. According to the aforementioned steps, the N-channel MIS transistor and the P-channel MIS transistor each having a homogeneous silicide phase can be formed.

A semiconductor device formed by the above described method in the present embodiment includes a first MIS transistor and a second MIS transistor formed on the semiconductor substrate 200. The first MIS transistor is of the N-channel type while the second MIS transistor is of the P-channel type, for example.

The first MIS transistor includes: the gate insulating film 201a made of SiON or the like and formed on the semiconductor substrate 200; the first gate electrode 214 made of NiSi of which constituent is entirely homogeneous and formed on the gate insulating film 201a; the sidewall 203a made of an insulating material and formed at each side face of the first gate electrode 214; the extension region (not shown) including the n-type impurity at a low concentration and formed in the region of the semiconductor substrate 200 which is located below each end of the first gate electrode 214; and the source region and the drain region (not shown) including the n-type impurity at a high concentration and formed in the respective regions of the semiconductor substrate 200 which are located below the respective sides of the first gate electrode 214.

The second MIS transistor includes: the gate insulating film 201b made of SiON or the like and formed on the semiconductor substrate 200; the second gate electrode 215 made of Ni₃Si of which constituent is entirely homogeneous and formed on the gate insulating film 201b; the sidewall 203b made of an insulating material and formed at each side face of the second gate electrode 215; the extension region (not shown) including the p-type impurity at a low concentration and formed in the region of the semiconductor substrate 200 which is located below each end of the second gate electrode 215; and the source region and the drain region (not shown) including the p-type impurity at a high concentration and formed in the respective regions of the semiconductor substrate 200 which are located below the respective sides of the second gate electrode 215.

According to the method in the present embodiment, the exposed part of the Ni film 209 is removed using the resist masks 212a, 212b formed on the Ni film 209 so that the Ni film (the partial Ni films 209a, 209b) is left only on the first gate silicon layer 202 and the second gate silicon layer 206. This enables Ni to be supplied evenly to every part of the first gate silicon layer 202 and the second gate silicon layer 206 in forming the silicide phases. As a result, gate electrodes having homogeneous silicide phases can be formed in a semiconductor device including a N-channel MIS transistor and a P-channel type MIS transistor, such as a CMOS, so that a MIS transistor of which characteristic are stabilized can be manufactured.

Further, according to the method in the present embodiment, each thickness ratio of the gate silicon layers to the Ni films formed thereon is adjusted so that FUSI gate electrodes having only desired silicide phases can be formed even in the condition where plural kinds of silicide phases would be formed. Hence, gates having silicide phases different from each other can be formed in a single wafer. It is noted that Ni is diffused in polysilicon in the silicide formation reaction, and therefore, desired silicide phases can be formed by referencing the volume ratios of the gate silicon layers to the Ni films formed thereon as a criterion if any thickness ratio of a gate silicon layer to a Ni film deviates from a predetermined value. For example, in the case where the mask 212a formed in the step shown in FIG. 3A is displaced from the end of the first gate silicon layer 202 in the direction of the gate length when viewed in plan, the thickness ratio of the first gate silicon layer 202 to the partial Ni film 209a may not necessarily be 1:1 if the range of displacement is within approximately 30 nm and the volume ratio of the first gate silicon layer 202 to the partial Ni film 209a is approximately 1:1.

In the semiconductor device in the present embodiment, a gate electrode made of NiSi having a favorable work function is formed in the N-channel MIS transistor while a gate electrode made of Ni₃Si having a favorably work function is formed in the P-channel MIS transistor. With this arrangement, the semiconductor device in the present embodiment exhibits performance higher than the conventional semiconductor devices.

It should be noted that the present embodiment exemplifies the case where the thicknesses of the first gate silicon layer 202, the second gate silicon layer 206, and the Ni film 209 before the silicide formation reaction are set to 60 nm, 20 nm, and 60 nm, respectively, but the film thicknesses of the first gate silicon layer 202, the second gate silicon layer 206, and the Ni film 209 are not limited to these values.

Further, description is made in the present embodiment to an example where plural kinds of Ni silicide having different crystal phases are formed by setting the different thicknesses between the first gate silicon layer 202 and the second gate silicon layer 206 in the steps shown in FIG. 2A to FIG. 2D. Plural kinds of Ni silicide can be formed by an alternative scheme. Namely, the first gate electrode 214 made of NiSi and the second gate electrode 216 made of Ni₃Si can be formed in such a way that the thicknesses of the first gate silicon layer 202 and the second gate silicon layer 206 are set equal to each other, the thickness of the partial Ni film 209a formed on the first gate silicon layer 202 is set substantially equal to the first gate silicon layer 202, and the thickness of the partial Ni film 209b formed on the second gate silicon layer 206 is set to approximately three times the thickness of the second gate silicon layer 206 (and the thickness of the first gate silicon layer 202).

In the method in the present invention, as shown in FIG. 3C, the upper level of the second gate electrode 215 having the Ni₃Si phase is lower than the upper level of the interlayer insulating film 204, wherein the upper level of the second gate electrode 215 can be adjusted appropriately by adjusting the thickness of the partial Ni film 209b formed on the second gate silicon layer 206. For example, when the thicknesses of the first gate silicon layer 202 and the second gate silicon layer 206 are set to 50 nm and 25 nm, respectively, in the step shown in FIG. 2C, and then, the partial Ni film 209a having the thickness of 50 nm and the partial Ni film 209b having the thickness of 75 nm are formed on the first gate silicon layer 202 and the second gate silicon layer 206, respectively, the upper level of the second gate electrode 215 approaches to the upper level of the interlayer insulating film 204.

The present embodiment refers to formation of the first gate electrode 214 having the NiSi phase and the second gate electrode 215 having the Ni₃Si phase, but a gate electrode having another silicide composition, such as Ni₂Si, of which constituent is homogeneous can be formed, as well.

Formation of gate electrodes made of Ni silicide has been described up to this point, but any gate electrode made of Si and a metal other than Ni, such as Co, Pt, or the like, may be formed. With the use of Co or the like, plural different kinds of silicide would be formed with Si similarly to the case using Ni, wherein employment of the present embodiment attains formation of a FUSI electrode of which constituent is homogeneous.

Moreover, the gate silicon layers are made of polysilicon in the present embodiment, but a FUSI electrode having a homogeneous silicide phase can be formed as well even when the gate silicon layer is made of amorphous silicon.

Furthermore, gate electrodes made of metal silicide of different kinds may be formed in same conductivity type MIS transistors according to needs. For example, a MIS transistor composing an internal circuit of a semiconductor integrated circuit and an I/O (input/output) transistor are different from each other in desired threshold voltage, and accordingly, the gate electrode of one of the MIS transistors may be made of NiSi when the gate electrode of the other MIS transistor is made of Ni₃Si.

The gate electrode of the N-channel MIS transistor and the gate electrode of the P-channel MIS transistor may be made of different kinds of metal silicide of which metals are different form each other. For example, the gate electrode of the N-channel MIS transistor is made of NiSi while the gate electrode of the P-channel MIS transistor is made of PtSi. This might attains higher performance of the semiconductor device.

The gate insulating film is made of SION in the present invention but may be formed of a high dielectric insulating film made of a metal oxide, such as Hf oxide, Zr oxide, or the like.

As described above, the semiconductor device manufacturing method in the present invention enables formation of a transistor including a FUSI gate electrode having a homogeneous silicide phase. The manufacturing method according to. the present invention can be utilized in various kinds of LSIs and the like including a miniaturized transistor.

What is claimed is:

1. A method for manufacturing a semiconductor device comprising the steps of:
(a) forming a first gate silicon layer on a semiconductor substrate with a first gate insulating film interposed;
(b) forming a metal film on the semiconductor substrate on which the first gate silicon layer is formed;
(c) forming a first mask on a part of the metal film which is located above the first gate silicon layer;
(d) removing a part of the metal film with the use of the first mask so as to leave the metal film on the first gate silicon layer; and
(e) forming a first gate electrode made of metal silicide by causing a reaction of the first gate silicon layer to the metal film left on the first gate silicon layer after the step (d).

2. The method for manufacturing a semiconductor device of claim 1, further comprising the steps of:
(f) forming a sidewall made of an insulating material on each side face of the first gate silicon layer after the step (a) and before the step (b); and
(g) setting the upper level of the first gate silicon layer to be lower than the upper end of the sidewall by removing an upper part of the first gate silicon layer before the step (b).

3. The method for manufacturing a semiconductor device of claim 1,
wherein the first mask is a resist mask.

4. The method for manufacturing a semiconductor device of claim 1,
wherein the step (c) includes the steps of:
forming an insulting film on the metal film; and
forming the first mask by polishing the thus formed insulating film.

5. The method for manufacturing a semiconductor device of claim 1,
wherein the first gate silicon layer is made of polysilicon.

6. The method for manufacturing a semiconductor device of claim 1, further comprising the step of:
(h) forming a second gate silicon layer on the semiconductor substrate with a second gate insulating film interposed, the second gate silicon layer having a thickness different from a thickness of the first gate silicon layer,
wherein in the step (b), the metal film is formed also on the second gate silicon layer,
in the step (c), a second mask is formed on a part of the metal film which is located above the second gate silicon layer,
in the step (d), a part of the metal film are removed using the fist mask and the second mask so as to leave the metal film on the first gate silicon layer and the second gate silicon layer, and
in the step (e), a second gate electrode made of metal silicide different in crystal phase from that of the first gate silicon layer is formed by causing a reaction of the second gate silicon layer to the metal film left on the second gate silicon layer while the first gate electrode is formed.

7. The method for manufacturing a semiconductor device of claim 6,
wherein the metal film is a Ni film, and
each of the first gate electrode and the second gate electrode are made of any one of NiSi, NiSi₂, and Ni₃Si.

8. The method for manufacturing a semiconductor device of claim 6,
wherein the metal film is a Co film, and
each of the first gate electrode and the second gate electrode are made of either one of CoSi and CoSi₂.

9. The method for manufacturing a semiconductor device of claim 6,
wherein the metal film is a Pt film, and
each of the first gate electrode and the second gate electrode are made of any one of PtSi, Pt₃Si, and Pt₂Si.

10. The method for manufacturing a semiconductor device of claim 1, further comprising the step of:
(i) forming a third gate silicon layer on the semiconductor substrate with a third gate insulating film interposed,
wherein in the step (b), the metal film is formed also on the third gate silicon layer so that a thickness of the metal film on the third gate silicon layer is different from a thickness of the metal film formed on the first gate silicon layer,
in the step (c), a third mask is formed on a part of the metal film which is located above the third gate silicon layer,
in the step (d), a part of the metal film is removed using the first mask and the third mask so as to leave the metal film on the first gate silicon layer and the third gate silicon layer, and
in the step (e), a third gate electrode made of metal silicide of which crystal phase is different from that of the first gate electrode is formed by causing a reaction of the third gate silicon layer to the metal film left on the third gate silicon layer while the first gate electrode is formed.

11. The method for manufacturing a semiconductor device of claim 1,
wherein the metal silicide formed in the step (e) is Ni silicide.

12. The method for manufacturing a semiconductor device of claim 1,
wherein the metal silicide formed in the step (e) is Co silicide.

13. The method for manufacturing a semiconductor device of claim 1,
wherein the metal silicide formed in the step (e) is Pt silicide.
